(19) United States
(12) Patent Application Publication
(10) Pub. No.: US 2016/0187406 A1
(43) Pub. Date: Jun. 30, 2016

(54) METHOD AND SYSTEM FOR IDENTIFYING LIGHTNING FAULT AND THE TYPE THEREOF IN THE OVERHEAD TRANSMISSION LINE

(71) Applicant: Shanghai Jiao Tong University, Shanghai (CN)

(72) Inventors: Yadong LIU, Shanghai (CN); Gehao Sheng, Shanghai (CN); Yong Qian, Shanghai (CN); Yue Hu, Shanghai (CN); Xiuchen Jiang, Shanghai (CN)

(73) Assignee: Shanghai Jiao Tong University

(21) Appl. No.: 14/659,603

(22) Filed: Mar. 16, 2015

(30) Foreign Application Priority Data
Dec. 24, 2014 (CN) 201410816946.5

(51) Int. Cl. G01R 31/02; G01R 31/12

(52) U.S. Cl. CPC G01R 31/021; G01R 31/12

(57) ABSTRACT

A method for identifying a lightning fault of an overhead transmission line (OTL) comprising determining a polarity of a travelling wave of each of three ABC phases subsequent to a single phase outage of the OTL. If the polarity of each phase is the same, the outage is a lightning fault and its type a back flashover; if not the same, proceed to the second step to determine a current change rate R of the fault phase. If R is larger than a threshold value, the outage is a lightning fault and its type a shielding failure; otherwise, the outage is a single-phase grounding fault. A system for identifying the lightning fault which comprises successively at least a group of fault detectors, a wireless communication module, a remote monitoring master station which adopts the above method to determine the fault type of the overhead transmission line.

### CROSS-REFERENCE TO RELATED APPLICATIONS

The subject application claims priority on Chinese Patent Application No. 201410816946.5 filed on Dec. 24, 2014. The contents and subject matter of the Chinese priority application are incorporated herein by reference.

### FIELD OF INVENTION

The present invention relates to fault identification in the overhead transmission line, particularly, method and system for identifying a lightning fault and its type in the overhead transmission line.

### BACKGROUND ART

Direct lightning stroke is the main cause for the overhead transmission line (OTL) fault as shown in the operation record in China and other countries. The direct lightning stroke may be categorized into the shielding failure and back flashover. When the lightning bypasses a shielding wire and directly hits the OTL, the incident is called a shielding failure. When the lightning hits the shielding wire or the tower top, if the grounding resistance is very high and the electric potential at the top of the tower is higher than that in the OTL, a flashover of the insulator strings triggered by the high voltage occurs which is called a back flashover. The shielding failure and back flashover differ in the mechanism and process as well as in the protection measures. The shielding failure mainly relates to the protection angle, while the back flashover mainly relates to the ground resistance of the tower and the dielectric strength of the transmission line. Correct identification of the shielding failure or back flashover provides the basis for accurate decision on a proper lightning protection measure, thereby reduces lightning accidents.

Currently, research on the shielding failure and back flashover mainly focuses on the design of the circuit stage. For the back flashover, the electromagnetic transient simulation analysis is mainly used, while for the shielding failure, electric geometry method analysis or its modified version is commonly used. When an OTL is in operation, differentiation between a shielding failure outage and a back flashover outage mostly depends on the experience of an engineer based on the current strength of the lightning and flashover situation of the insulator strings, which is therefore subjective and lacks credibility.

### SUMMARY OF THE INVENTION

The present invention provides a method for identifying a lightning fault and the type thereof. The method of the present invention effectively identifies a lightning fault or a line fault in case of an OTL outage as well as the type of the lightning fault.

The present invention further provides a system for identifying a lightning fault and its type. The system of the present invention effectively identifies a lightning fault or a line fault in case of an OTL outage as well as the type of the lightning fault.

The method of the present invention for identifying a lightning fault and its type of an OTL comprises the following steps.

The first step is to determine the polarity of a travelling wave of each of the three ABC phases after a single phase outage of an OTL. If the polarity of each phase is the same, the outage is determined to be a lightning fault, and the type thereof is determined to be a back flashover; if the polarity of each phase does not equal to each other, proceed to the next step.

The second step is to determine the current change rate R of the fault phase. If R is larger than a threshold value, the outage is determined to be a lightning fault, and the type thereof is determined to be a shielding failure; if R is not larger than the threshold value, the outage is determined to be a single-phase grounding fault. R is defined as follows:

R=|max(i(s))|/t_{w} ,

wherein t_{w} is a half wave length of a first captured travelling wave, i(s) represents the first captured travelling wave, and max(i(s)) represents an amp litude of the first captured travelling wave.

The identification method to detect a lightning fault and its type of an OTL of the present invention is based on the time domain characteristics of the fault-induced travelling wave and realizes an effective identification of a lightning fault or a line fault of an OTL and the type (including shielding failure and back flashover) of the lightning fault, and thus, provides an accurate basis for a decision on a proper lightning protection measure. The working principle is as follows: the travelling wave generated by a back flashover fault, a shielding failure fault, or a line fault shows distinct characteristic, which forms the basis for the determination of the fault type. Specifically, the polarity of each of the three phases in the travelling wave triggered by the back flashover fault is the same, the polarity of each of the three phases in the travelling wave triggered by a shielding fault or a single-phase grounding fault (line fault) is not the same. Furthermore, the current change rate R of the travelling wave of a shielding failure and a single-phase grounding fault lies in different intervals, and hence a threshold may be employed for differentiating the intervals. If the current change rate R lies in the interval exceeding the threshold, the fault is determined to be a shielding failure, otherwise the fault is determined to be a line fault. The current change rate R is the ratio of the absolute amplitude of the first captured travelling wave over the half wave length.

Furthermore, in the identification method to detect a lightning fault and its type of an OTL of the present invention, the threshold is selected from the range between 129.8-365.6 A/μs.

The reason for restricting the threshold to the above range is as follows: 129.8 A/μs is the upper limit of the current change rate R of the first captured travelling wave of a single-phase grounding fault, and 365.6 A/μs is the lower limit of the current change rate R of the first captured travelling wave of a shielding failure. Therefore, the selection of the threshold within the range 129.8-365.6A/μs ensures correct differentiation between a single-phase grounding fault and a shielding failure. Computation of the two endpoints of the range is as follows.

First, the computation process of the upper limit 129.8 A/μs of the current change rate R of the first captured travelling wave of a single-phase grounding fault is analyzed.

Supposing that the OTL is single-phase grounded at A, and the boundary is as follows:

$$\{ \begin{matrix}{u}_{fltA} + {i}_{fltA} {R}_{fltA} = - {U}_{over} \\ {i}_{fltB} = {i}_{fltC} = 0\end{matrix} \qquad ( 1 )$$

Wherein Uₒᵥₑᵣ is the line voltage prior to the line failure, i_{fltA}, i_{fltB}, i^{fltC} are the travelling waves fault current of the three phases A, B, C, respectively, u_{fltA} is the virtual fault voltage of phase A, and R^{fltA} ᵢs the fault transition resistance of phase A.

The single-phase boundary condition leads to:

i₀=i₁=i₂=i_{fltA}/3 (2)

Wherein i₀ is the ground model component, i₁ is the 1 model component, and i₂ is the 2 model component (ground model component is alternatively named in the art as zero model component, and 1 model and 2 model components as line model components).

From the equivalent circuit with A being single-phase grounded and Equations (1) and (2) above, the amplitude I_{trnsA} of the travelling wave fault current of phase A can be obtained as shown in Equation (3).

$${I}_{trnsA} = - \frac{3 {U}_{over}}{{Z}_{mod 0} + {Z}_{mod 1} + {Z}_{mod 2} + 6 {R}_{fltA}} \qquad ( 3 )$$

Wherein Z_{mod0} is the ground model wave impedance, Z_{mod1} is the 1 model wave impedance, and Z_{mod2} [symbol] the 2 model wave impedance, 1 model wave impedance and 2 model wave impedance is theoretically the same.

Table 1 summarizes the model wave impedances of a typical 500 kV OTL:

TABLE 1

| | | | | | Line | Ground |
|---|---|---|---|---|---|---|
| | Positive | Zero | Positive | Zero | mode wave | mode wave |
| | sequence | sequence | sequence | sequence | impedance | impedance |
| Tower type | X_{L1}(Ω/km) | X_{L0}(Ω/km) | C₁(nF/km) | C₀(nF/km) | Z₁(Ω) | Z₀(Ω) |
| 5D-Z1 | 0.268 | 0.716 | 13.58 | 7.87 | 250.64 | 538.14 |
| 5A-M1 | 0.258 | 0.681 | 13.906 | 7.287 | 243.02 | 545.41 |
| 5AZB1 | 0.265 | 0.671 | 13.634 | 7.532 | 248.73 | 532.51 |
| Compact | 0.201 | 0.741 | 17.687 | 7.081 | 190.19 | 577.15 |
| single | | | | | | |
| Compact | 0.201 | 0.748 | 17.733 | 7.516 | 189.95 | 562.84 |
| double | | | | | | |
| 2 × 5A-ZM1 | 0.257 | 0.632 | 13.916 | 7.416 | 242.46 | 520.83 |
| 2 × 5A-ZB1 | 0.265 | 0.620 | 13.658 | 7.685 | 248.52 | 506.76 |

### Since

$$\vert {I}_{trnsA} \vert = \vert \frac{3 {U}_{over}}{{Z}_{mod 0} + {Z}_{mod 1} + {Z}_{mod 2} + 6 {R}_{fltA}} \vert < \vert \frac{3 {U}_{over}}{{Z}_{mod 0} + {Z}_{mod 1} + {Z}_{mod 2}} \vert ,$$

and with combination of the above equation and Table 1, the maximum value max(i(s)) of the first captured travelling wave with the fault phase as the single grounded phase is obtained as

$$\vert \frac{3 {U}_{over}}{{Z}_{mod 0} + {Z}_{mod 1} + {Z}_{mod 2}} \vert ,$$

wherein the values for the mode impedance Z_{mod0} Z_{mod1} and Z_{mod2} are taken so that the total value of the three is the smallest mode impedance in Table 1, that is, the mode impedances corresponding to the “compact double,” and the line voltage prior to fault Uₒᵥₑᵣ of the 500 kV OTL is 500*1000*1.414/1.732=408 kV. Hence, the maximum value of the amplitude of the first travelling wave with the fault phase as the single grounded phase is

$$\vert \frac{3 {U}_{over}}{{Z}_{mod 0} + {Z}_{mod 1} + {Z}_{mod 2}} \vert = 1298 A .$$

Considering the voltage range of the OTL, variance in circuit distributing parameters, and over-voltage during the switching , the safety factor is taken as 2.5 times, and therefore, the maximum value of the amplitude of the first travelling wave with the fault phase as the single grounded phase of a 500 kV OTL is taken as 3245 A.

In the short time span after an OTL single grounded phase outage, the fault current travelling wave may be viewed as a step signal. The fault current sensor, which comprises a Rogowski coil and an integrator, is in fact a bandwidth filter. The time constant is determined by the external resistor of the Rogowski coil and the parameters of the integrator, and therefore the half wave length of the fault current travelling wave of the single-phase grounding fault is determined by the external resistor. In the present invention, by setting the bandwidth of the sensor, the half wave length t_{w} of the first captured travelling wave of the single-phase grounding fault is equal to 25 us.

Hence, according to the equation R=|max(i(s))|/t_{w}, the upper limit of the current change rate R of the first captured travelling wave of the single-phase grounding fault is obtained as 3245 A/25 μs=129.8 A/μs.

Next, analyze the computation process to obtain the lower limit 365.6 A/μs of the current change rate R of the first captured travelling wave of a shielding failure.

Shielding failure is caused by an over-voltage which is triggered by the lightning travelling wave along the OTL and exceeds the breakdown voltage of the insulator. Let the maximum breakdown voltage of the insulator be Vₘₐₓ, generally speaking, Vₘₐₓ for a 500 kV OTL is at least 1675 kV. When a shielding failure occurs, the amplitude of the travelling wave is determined by Vₘₐₓ and the phase power voltage V_{f}. The V_{f} maximum is 408 kV for a 500 kV OTL. If the phase power voltage and the lightning travelling wave have the same polarity, the fault current travelling wave Vₜᵣᵥₗ is the sum of Vₘₐₓ and V_{f}. In the case of the opposite polarity, Vₜᵣᵥₗ is Vₘₐₓ minus V_{f}. For a 500 kV OTL, the minimum of Vₜᵣᵥₗ is 1675−408=1267 kV. Meanwhile, the computation of the maximum max(i(s)) of the amplitude of the first travelling wave of

$$\vert \frac{3 {U}_{over}}{{Z}_{mod 0} + {Z}_{mod 1} + {Z}_{mod 2}} \vert$$

requires that the line mode impedance takes its maximum value, that is, the value corresponding to 5D-Z1 on Table 1. Thus, the maximum of the amplitude of the first captured travelling wave in a shielding failure is computed as 3*1266.81*1000/(250.64+250.64+538.14). Computed from the the equation, the minimum of the amplitude max(i(s)) of the first captured travelling wave in a shielding failure is 3656 A.

When a shielding failure occurs, the half wave length of the fault current travelling wave is much shorter than the lightning current wavelength, similar to a chopped lightning wave. In the high voltage test standard, the chopped lightning wavelength is about 6 μs, thus, the half wavelength of the lightning current when a shielding failure occurs is about several μs, and its maximum value is 10 μs.

Therefore, the equation R=|max(i(s))|/t_{w} leads to that the lower limit of the current change rate R of the first captured travelling wave in a single-phase grounding failure is 3656 A/10 μs=365.6 A/μs.

Preferably, in the identification method to detect a lightning fault and its type of an OTL of the present invention, the threshold value is chosen as 150 A/μs.

The identification system to detect a lightning fault and its type of an OTL of the present invention comprises the following components:

At least a group of fault detectors installed on the OTL; each group of the fault detectors comprises three fault detectors correspondingly capturing a travelling wave of each of the ABC three phases;

A wireless communication module wirelessly connected to at least one of the group of fault detectors for receiving the travelling waves transmitted from the fault detectors;

A remote monitoring master station connected to the wireless communication module for determining the polarity of the travelling wave of each of the ABC three phases according to the received travelling waves at occurrence of an outage of the OTL. If the polarity of each phase is the same, the outage is determined to be a lightning fault, and a type thereof is determined to be a back flashover. If the polarity of each phase isn't the same, depending on the measured current change rate R of the fault phase, if R is larger than a threshold, the outage is determined to be a lightning fault, and a type thereof is determined to be a shielding failure; if R is not larger than the threshold, the outage is determined to be a single-phase grounding fault; wherein

R=|max(i(s))|/t_{w},

t_{w} is a half wave length of a first captured travelling wave, i(s) represents the first captured travelling wave, and max(i(s)) represents an amp litude of the first captured travelling wave.

In the identification system to detect a lightning fault and its type of an OTL of the present invention, the fault detectors detect travelling waves generated in an outage, the wireless communication module transmits the travelling waves to the remote monitoring master station, and the remote monitoring master station receives and analyzes the travelling waves. It thus realizes an effective identification of a lightning fault or a line fault of an OTL, and an effective identification of the type (including shielding failure and back flashover) of the lightning fault, and provides an accurate basis for a decision on adoption of proper lightning prevention measures. The principle thereof, being detailed in the foregoing, shall not be repeated again.

Preferably, in the identification system to detect a lightning fault and its type of an OTL of the present invention, the threshold value is selected from the range 129.8-365.6 A/μs.

Furthermore, in the identification system to detect a lightning fault and its type of an OTL, the wireless communication module comprises a short-range wireless communication network and a remote wireless communication network, wherein the travelling waves of each phase detected by the three fault detectors in each group are transmitted by the short-range wireless communication network to a specific node, and then transmitted by the remote wireless network to the remote monitoring master station.

Preferably, in the above identification system to detect a lightning fault and its type of an OTL, the remote wireless communication network is a network of GPRS/CDMA/GSM.

Preferably, in the above identification system to detect a lightning fault and its type of an OTL, the short-range wireless network is a ZIGBEE communication network.

Furthermore, in the above identification system to detect a lightning fault and its type of an OTL, each of the fault detectors comprises a broadband Rogowski coil.

Yet furthermore, in the above identification system to detect a lightning fault and its type of an OTL, the broadband Rogowski coil is connected to an integrator.

The method and system for identifying lightning fault and its type of an OTL of the present invention is advantageous in that:

1) The determination of the fault type of the OTL requires no input of personal experience from data collection to data analysis, and is thus more objective and credible compared with the prior art; and

2) It is capable of correctly and effectively determining a lightning fault or a line fault of an OTL, and the types of shielding failure and back flashover in the lightning fault, and thus provides an accurate basis for a decision on adoption of proper lightning prevention measures to reduce lightning accidents; and

3) It provides guidance for subsequent repair and maintenance and is applicable in research and engineering.

### BRIEF DESCRIPTION OF THE DRAWINGS

FIG. 1 is a circuit diagram showing the equivalent circuit when phase A of an OTL is single-phase grounded.

FIG. 2 is a flow chart exemplifying the method for identifying a lightning fault and its type of an OTL of the present invention in one of the embodiments.

FIG. 3 is a schematic diagram showing one embodiment of the system for identifying a lightning fault and its type of an OTL of the present invention.

FIG. 4 shows the waveform of the travelling wave detected by the fault detector in one embodiment of the present invention.

FIG. 5 shows the waveform of the travelling wave detected by the fault detector in another embodiment of the present invention.

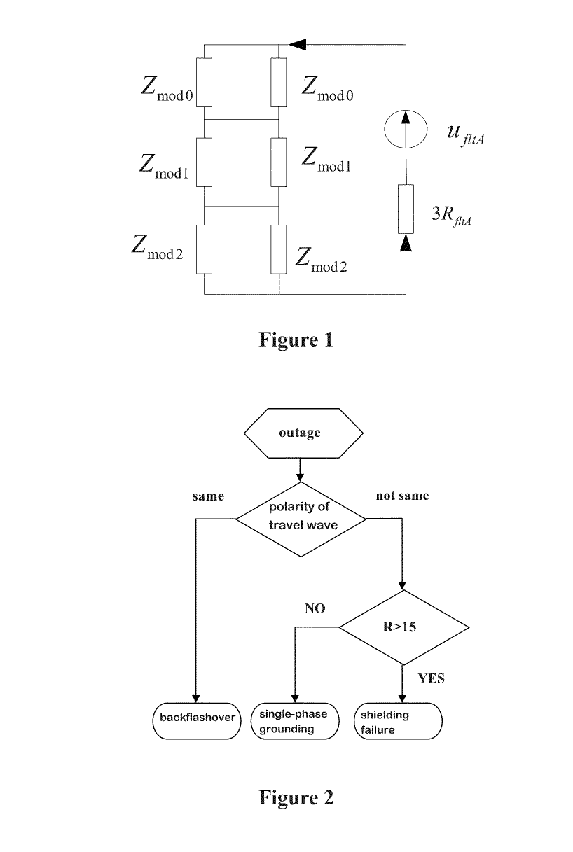

### DETAILED DESCRIPTION OF THE INVENTION AND EMBODIMENTS

In combination with drawings and embodiments hereunder provided, the method and system for identifying and detecting a lightning fault and its type of an OTL of the present invention is further expounded.

In the explanation on the principle of the method and system for identifying lightning fault and its type of an OTL of the present invention, a critical physical quantity R, namely, the current change rate is mentioned. It is prescribed in certain embodiments to be not less than 365.6 A/μs for a shielding failure fault, and not more than 129.8 A/μs for a single-phase grounding fault. A detailed explanation for determining the value is given as follows.

The current change rate R is expressed as

R=|max(i(s))|/t_{w},

wherein, t_{w} is the half wave length of the first captured travelling wave, i(s) represents the first captured travelling wave, and max (i(s)) represents an amplitude of the first captured travelling wave.

It follows from the above equation that the range of the current change rate R is related to that of the amplitude of the travelling wave and that of the half wave length.

First, analyze the computation process for the upper limit 129.8 A/μs of the current change rate R of the first captured travelling wave of a single-phase grounding fault.

Suppose the OTL is single-phase grounded at A, and the boundary is as follows:

$$\{ \begin{matrix}{u}_{fltA} + {i}_{fltA} {R}_{fltA} = - {U}_{over} \\ {i}_{fltB} = {i}_{fltC} = 0\end{matrix} \qquad ( 1 )$$

wherein U^{over} is the line voltage prior to the line failure, i_{fltA}, i_{fltB}, i_{fltC} are the travelling waves fault current of the three phases A, B, C respectively, u_{fltA} is the virtual fault voltage of phase A, and R_{fltA} is the fault transition resistance of phase A.

The single-phase boundary condition leads to:

i₀=i₁=i₂=i_{fltA}/3 (2)

wherein i₀ is the ground model component, is the i₁ model component, and i₂ is the 2 model component (ground model component is alternatively named in the art as zero model component, and 1 model and 2 model components as line model components).

From the equivalent circuit with A being single-phase grounded, and from the equations (1) and (2), it is inferred that the amplitude I^{trnsA} of the travelling wave fault current of phase A is shown in equation (3).

$${I}_{trnsA} = - \frac{3 {U}_{over}}{{Z}_{mod 0} + {Z}_{mod 1} + {Z}_{mod 2} + 6 {R}_{fltA}} \qquad ( 3 )$$

wherein Z_{mod0} is the ground model wave impedance, Z_{mod1} is the 1 model wave impedance, and Z_{mod2}z∓ the 2 model wave impedance, 1 model wave impedance and 2 model wave impedance is theoretically the same.

The model wave impedances of a typical 500 kV OTL is summarized in Table 1. Since

$$\vert {I}_{trnsA} \vert = \vert \frac{3 {U}_{over}}{{Z}_{mod 0} + {Z}_{mod 1} + {Z}_{mod 2} + 6 {R}_{fltA}} \vert < \vert \frac{3 {U}_{over}}{{Z}_{mod 0} + {Z}_{mod 1} + {Z}_{mod 2}} \vert ,$$

and with combination of the above equation and Table 1, it is inferred that the maximum value max(i(s)) of the first captured travelling wave with the fault phase as the single grounded phase is

$$\vert \frac{3 {U}_{over}}{{Z}_{mod 0} + {Z}_{mod 1} + {Z}_{mod 2}} \vert ,$$

wherein the values for the mode impedances Z_{mod0}, Z_{mod1} and Z_{mod2} are taken so that the total value of the three is the smallest mode impedances in Table 1, that is, the mode impedances corresponding to “compact double,” and the line voltage prior to fault Uₒᵥₑᵣ of the 500 kV OTL is 500*1000*1.414/1.732=408 kV. Hence, the maximum value of the amplitude of the first travelling wave with the fault phase as the single grounded phase is

$$\vert \frac{3 {U}_{over}}{{Z}_{mod 0} + {Z}_{mod 1} + {Z}_{mod 2}} \vert = 1298 A .$$

Considering the voltage range of the OTL, the variance in circuit distributing parameters, and over-voltage during the switching , the safety factor is taken as 2.5 times, and therefore, the maximum value of the amplitude of the first travelling wave with the fault phase as the single grounded phase of a 500 kV OTL is taken as 3245 A.

In the short time span after the OTL single grounded phase outage, the fault current travelling wave may be viewed as a step signal. The fault current sensor, which comprises a Rogowski coil and an integrator, is in fact a bandwidth filter. The time constant is determined by the external resistor of the Rogowski coil and the parameters of the integrator, and therefore the half wave length of the fault current travelling wave of the single-phase grounding fault is determined by the external resistor. In the present technical solution, by setting the bandwidth of the sensor, the half wave length t_{w} of the first captured travelling wave of the single-phase grounding fault is equal to 25 μs.

Hence, according to the equation R=|max(i(s))|/t_{w}, the upper limit of the current change rate R of the first captured travelling wave of a single-phase grounding fault is obtained as 3245 A/25 μs=129.8 A/μs.

Next, analyze the computation process to obtain the lower limit 365.6 A/μs of the current change rate R of the first captured travelling wave of a shielding failure.

The shielding failure is caused by an over-voltage which is triggered by the lightning travelling wave along the OTL and exceeds the breakdown voltage of the insulator. Let the maximum breakdown voltage of the insulator be Vₘₐₓ, generally speaking, at least 1675 kV for a 500 kV OTL. When shielding failure occurs, the amplitude of the travelling wave is determined by Vₘₐₓ and the phase power voltage V_{f}. The maximum is 408 kV for a 500 kV OTL. If the phase power voltage and the lightning travelling wave have the same polarity, the fault current travelling wave Vₜᵣᵥₗ is the sum of Vₘₐₓ and V_{f}. In the case of opposite polarity, Vₜᵣᵥₗ is Vₘₐₓ minus V_{f}. For a 500 kV OTL, the minimum of Vₜᵣᵥₗ is 1675−408=1267 kV. Meanwhile, computation of the maximum max(i(s)) of the amplitude of the first travelling wave of

$$\vert \frac{3 {U}_{over}}{{Z}_{mod 0} + {Z}_{mod 1} + {Z}_{mod 2}} \vert$$

requires that the line mode impedance takes its maximum, that is, the value corresponding to 5D-Z1 on Table 1. Thus the maximum of the amplitude of the first captured travelling wave in a shielding failure is computed as 3*1266.81*1000/(250.64+250.64+538.14). Computed from the the equation, the minimum of the amplitude max(i(s)) of the first captured travelling wave in a shielding failure is 3656 A.

When a shielding failure occurs, the half wave length of the fault current travelling wave is much shorter than lightning current wavelength, similar to a chopped lightning wave. In a high voltage test standard, the chopped lightning wavelength is about 6 μs, thus the half wavelength of the lightning current when a shielding failure occurs is about several 6 μs, and its maximum value is 10 μs.

Therefore, the equation R=|max(i(s))|/t_{w} leads to the lower limit of the current change rate R of the first captured travelling wave in a single-phase grounding failure 3656 A/10 μs=365.6 A/μs.

FIG. 2 describes a process for an embodiment of the method of the present invention. As is shown on FIG. 2, an identification method to detect a lightning fault and its type of an OTL of the present invention comprises the following steps.

The first step is to determine the polarity of a travelling wave of each of the three ABC phases subsequent to a single phase outage of an OTL. If the polarity of each phase is the same, the outage is determined to be a lightning fault, and a type thereof is determined to be a back flashover; if the polarity of each phase does not equal to each other, proceed to the second step.

The second step is to determine a current change rate R of the fault phase. With the threshold being in the range 129.8-365.6 A/μs, here it is chosen to be 150 A/μs. If R is larger than 150 A/μs, the outage is determined to be a lightning fault, and a type thereof is determined to be a shielding failure; if R is not larger than 150 A/μs, the outage is determined to be a single-phase grounding fault; wherein

R=|max(i(s))|/t_{w},

wherein, t_{w} is a half wave length of a first captured travelling wave, i(s) represents the first captured travelling wave, and max(i(s)) represents an amplitude of the first captured travelling wave.

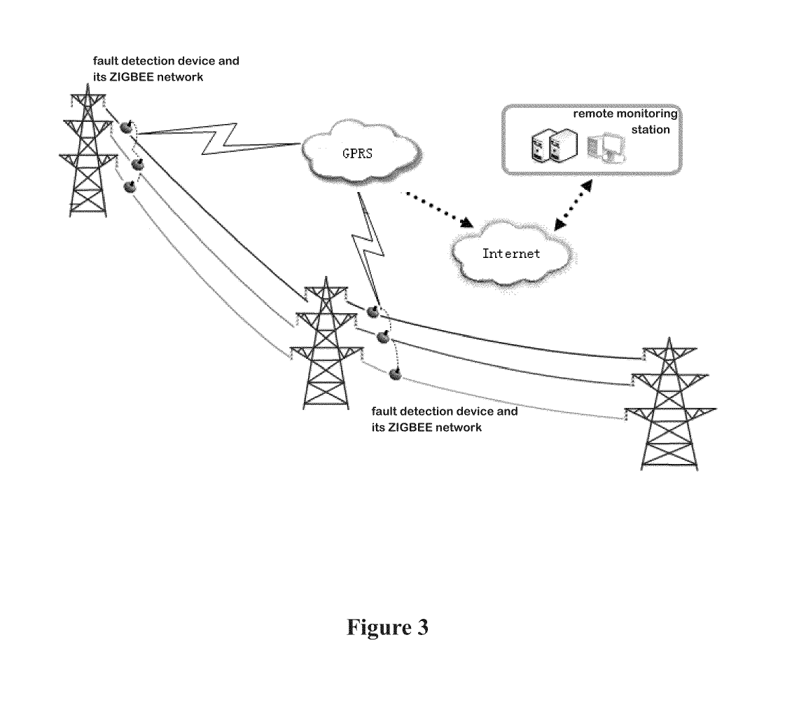

FIG. 3 shows an embodiment of the system of the present invention.

As is shown on FIG. 3, the system for identifying a lightning fault and its type of an OTL comprises various groups of fault detectors installed on the OTL; each group of the fault detectors comprises three fault detectors, the three fault detectors comprise a broadband Rogowski coil connected with an integrator and correspondingly capturing a travelling wave of one phase of the ABC three phases; a wireless communication module connected wirelessly to the fault detectors for receiving the travelling waves transmitted from the fault detectors; a remote monitoring master station connected to the wireless communication module for determining a polarity of travelling wave of each of the ABC three phases according to the received travelling waves at occurrence of an outage of the OTL. If the polarity of each phase is the same, the outage is determined to be a lightning fault, and a type thereof is determined to be a back flashover; if the polarity of each phase is not the same, proceed to measure a current change rate R of the fault phase, and select the threshold as 150 A/μs. If R is larger than 150 A/μs, the outage is determined to be a lightning fault, and a type thereof is determined to be a shielding failure; if R is not larger than 150 A/μs, the outage is determined to be a single-phase grounding fault; wherein

R=|max(i(s))|/t_{w}

wherein t_{w} is a half wave length of a first captured travelling wave, i(s) represents the first captured travelling wave, and max(i(s)) represents an amplitude of the first captured travelling wave.

In the above system, the wireless communication module comprises a short-range wireless ZIGBEE communication network and a remote wireless GPRS communication network, wherein the travelling waves detected by the three fault detectors of each group of fault detectors are transmitted by the short-range wireless ZIGBEE communication network to a specific node, and then transmitted by the remote wireless GRPS communication network and the Internet to the remote monitoring master station. The fault detectors may be powered by CT or in combination with back-up batteries.

Next, the present invention is confirmed of its effects with the following examples.

### EXAMPLE 1

A 500 kV A, B tower double circuit OTL, with a line length of 186.642 km, has a group of fault detectors installed at tower #267 at a distance of 125.37 km.

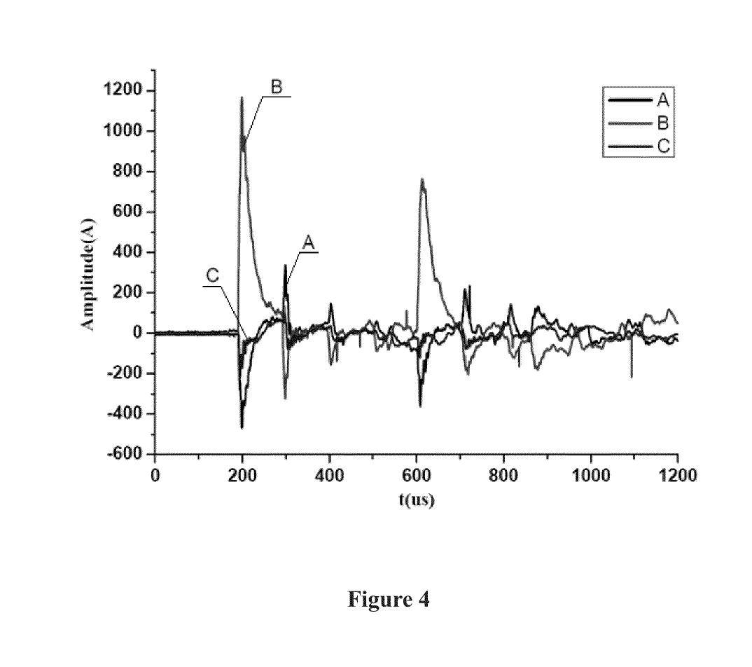

One day, an outage occurs. The waveform of the travelling wave recorded by the fault detectors installed at tower #267 is shown on FIG. 4, with the wave front characteristic parameters thereof shown on Table 2.

TABLE 2
Wave Front Characteristic Parameters of a Fault Travelling Wave.

| | | Amplitude | Half wave | Current change |
|---|---|---|---|---|
| phase | polarity | (A) | length (us) | rate R (A/us) |
| A | − | 470.1 | 22 | 21.3 |
| B | + | 1155 | 25 | 46.2 |
| C | − | 225.6 | 15 | 15.4 |

Table 2 shows that phase B is opposite in polarity against AC phases, from which it can be preliminarily concluded that the outage is a shielding failure or a line fault. The current change rate R of phase B is 46.2, which is smaller than 150, and therefore, it is determined to be a single-phase grounding fault.

Inspection shows that in the 500 kV A line has a right ground wire broken between tower 35 and 36. The broken wire has one section hanging from the 500 kV B line and drooping to the ground, it has the other section (N35) hanging in a lower position from the other OTL and having a length of 730 meters. The inspection findings confirm the conclusion of the embodiment.

### EXAMPLE 2

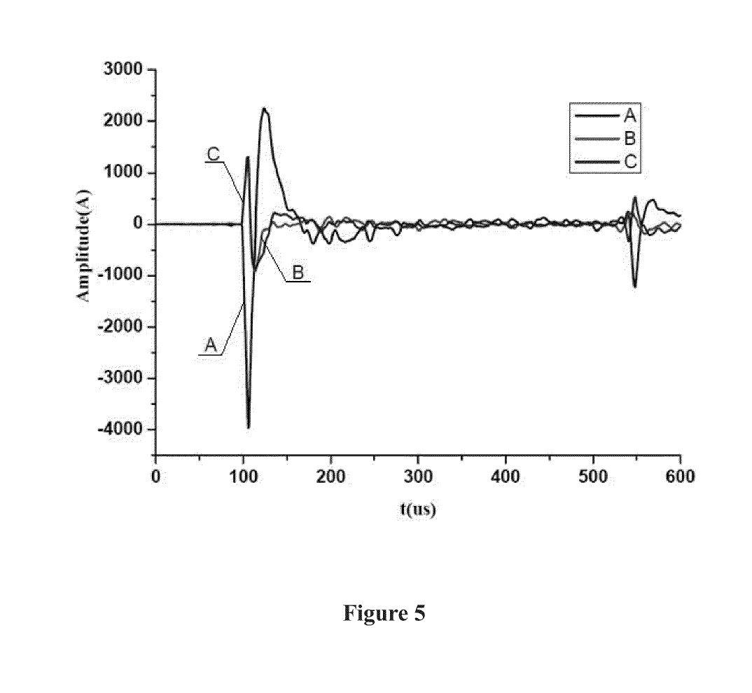

The 500 kV XX has a total length of 148.440 km. One day an outage occurs on phase A. The waveform of the travelling wave detected by the fault detectors is shown on FIG. 5, with the wave front characteristic parameters thereof shown on Table 3.

TABLE 3
Wave Front Characteristic Parameters
of Anther Fault Travelling Wave.

| | | Amplitude | Half wave | Current change |
|---|---|---|---|---|
| phase | polarity | (A) | length (us) | rate R (A/us) |
| A | − | 3969 | 10.5 | 378.00 |
| B | + | 1298 | 8.9 | 145.84 |
| C | + | 1309 | 8.9 | 147.08 |

Table 3 shows that phase A is opposite in polarity against the BC phases, from which it can be preliminarily concluded that a shielding failure or line fault has occurred. The current change rate of phase A is 378, bigger than 150, and therefore it is a shielding failure. Inspection shows that along the 500 KV OTL, the glass insulator and the grading ring of jumper of phase A in one of the towers have discharge burns, the inspection findings confirms the conclusion drawn from the embodiment.

The present invention shall not be limited to the above preferred embodiments, and any modification, refinement, substitute, combination, or simplification without departing from the spirit and principle of the present invention shall fall within its scope.

We claim:

1. A method for identifying a lightning fault of an overhead transmission line comprising
determining a polarity of a travelling wave of each of three A, B, and C phases subsequent to a single phase outage of an overhead transmission line,
identifying the outage as a lightning fault and a type of the outage as a back flashover, when the polarity of each phase is same;
determining a current change rate R of the fault phase, when the polarity of each phase is not the same,
comparing the current change rate R with a threshold value, and
identifying the outage as a lightning fault and the type of the outage as a shielding failure, when R is larger than the threshold value, the outage as a single-phase grounding fault, when R is not larger than the threshold value,
wherein the current change rate R is determined by
R=|max(i(s))|t_{w},
t_{w} is a half wave length of a first captured travelling wave, i(s) represents the first captured travelling wave, and max(i(s)) represents an amp litude of the first captured travelling wave.

2. The method for identifying a lightning fault of an overhead transmission line as described in claim 1, wherein the threshold value is selected from a range 129.8-365.6 A/μs.

3. The method for identifying a lightning fault of an overhead transmission line as described in claim 1, wherein the threshold value is 150 A/μs.

4. A system for identifying a lightning fault of an overhead transmission, comprising
at least a group of fault detectors installed on an overhead transmission line, each group of the fault detectors comprising three fault detectors, and each of the three fault detectors respectively capturing an A, B, and C phases of a travelling wave,
a wireless communication module wireles sly connected to the at least one group of the fault detectors for receiving the travelling wave transmitted from the fault detectors, and
a remote monitoring master station connected to the wireless communication module for determining a polarity of travelling wave of each of the ABC three phases according to the received travelling waves at occurrence of an outage of the overhead transmission line.

5. The system for identifying a lightning fault of an overhead transmission line as described in claim 4, wherein the wireless communication module comprises a short-range wireless communication network and a remote wireless communication network, the travelling waves detected by the three fault detectors of each group of fault detectors are transmitted by the short-range wireless communication network to a specific node, and then transmitted by the remote wireless network to the remote monitoring master station.

6. The system for identifying a lightning fault of an overhead transmission line as described in claim 5, wherein the remote wireless communication network is a network of GPRS, CDMA, or GSM.

7. The system for identifying a lightning fault of an overhead transmission line as described in claim 5, wherein the short-range wireless communication network is a ZIGBEE communication network.

8. The system for identifying a lightning fault of an overhead transmission line as described in claim 4, wherein each of the fault detectors comprises a broadband Rogowski coil.

9. The system for identifying a lightning fault of an overhead transmission line as described in claim 8, wherein the broadband Rogowski coil is connected to an integrator.
